(19) United States
(12) Patent Application Publication
(10) Pub. No.: US 2014/0145641 A1
(43) Pub. Date: May 29, 2014

(54) Single Wire Signal Process Method and Circuit

(71) Applicant: ANPEC ELECTRONICS CORPORATION, Hsin-Chu (TW)

(72) Inventors: Chin-Hong Chen, Taichung City (TW); San-Yi Li, Tainan City (TW); Chieh-Wen Cheng, Hsinchu City (TW)

(73) Assignee: ANPEC ELECTRONICS CORPORATION, Hsin-Chu (TW)

(21) Appl. No.: 13/771,018

(22) Filed: Feb. 19, 2013

(30) Foreign Application Priority Data
Nov. 28, 2012 (TW) 101144447

(51) Int. Cl. H03M 7/40; H05B 33/08

(52) U.S. Cl. CPC H03M 7/40; H05B 33/0833
USPC 315/291; 341/67

(57) ABSTRACT

A signal processing method for a single wire, includes receiving an input signal via the single wire, wherein the input signal includes a plurality of pulse signals; generating a plurality of bits corresponding to the plurality of pulse signals according to a plurality of widths of the plurality of pulse signals and forming a source code; and decoding the source code to generate a control code; wherein when a width of a first pulse signal of the plurality of pulse signals is smaller than a first duration, a first bit corresponding to the first pulse signal is a first bit value and when a width of a second pulse signal of the plurality of pulse signals is greater than a second duration, a second bit corresponding to the second pulse signal is a second bit value.

### BACKGROUND OF THE INVENTION

1. Field of the Invention

The present invention relates to a signal processing method and related circuit, and more particularly, to a signal processing method and related circuit capable of receiving an input signal via a single wire to decrease pin number.

2. Description of the Prior Art

The digitization and integration of an integrated circuit (IC) have become a trend. However, with the needs of the many special applications for life, a stand alone IC with analog applications is still essential, such as the IC for driving a light emitting diode (LED) or the IC for touch sensing. Most of the stand alone ICs are designed for the special specifications or requirements, so the internal circuits are also designed for the specific applications. Thus, the related control system of the stand alone IC is not controlled by an internal central processor with stored control codes such as the integrated IC, and often requires receiving a control signal from an external control element via a pin of the IC to convert as control information, so as to control the external component, such as the brightness of the LED. The conventional control system utilizes multiple pins for receiving the external control signals, for example utilizing an inter-integrated circuit (I²C) bus communication interface. The I²C bus communication interface respectively utilizes a serial data (SDA) pin and a serial clock (SCL) pinto serially receive and decode to the control information, so as to control the external components.

However, with the evolution of the chip manufacturing process, the area of the internal circuit in the stand-alone IC is reduced. If the control system of the stand-alone IC still utilizes multiple pins to receive the external control signals, the pad number of the IC is increased resulting in the chip area being large due to the outline increased pad number, and simultaneously the packaging cost is increased. On the other hand, under a situation for utilizing the same pin number, if the pin number of the control system is reduced, the control system may reserve more pins for other purposes. Thus, there is a need for improvement of the prior art.

### SUMMARY OF THE INVENTION

It is therefore an objective of the present invention to provide a signal processing method and related circuit capable of receiving an input signal via a single wire to decrease pin number.

The present invention discloses a signal processing method, for a single wire, comprising receiving an input signal via the single wire, wherein the input signal comprises a plurality of pulse signals, generating a plurality of bits corresponding to the plurality of pulse signals according to a plurality of widths of the plurality of pulse signals and forming a source code, and decoding the source code to generate a control code, wherein when a width of a first pulse signal of the plurality of pulse signals is smaller than a first duration, a first bit corresponding to the first pulse signal is a first bit value, and when a width of a second pulse signal of the plurality of pulse signals is greater than a second duration, a second bit corresponding to the second pulse signal is a second bit value.

The present invention further discloses a signal processing circuit, for a single wire, comprising a single input terminal for receiving an input signal via the single wire, wherein the input signal comprises a plurality of pulse signals, a pulse width detection unit for generating a plurality of bits corresponding to the plurality of pulse signals according to a plurality of widths of the plurality of pulse signals and forming a source code, and a decoding unit for decoding the source code to generate a control code, wherein when a width of a first pulse signal of the plurality of pulse signals is smaller than a first duration, a first bit corresponding to the first pulse signal is a first bit value, and when a width of a second pulse signal of the plurality of pulse signals is greater than a second duration, a second bit corresponding to the second pulse signal is a second bit value.

The present invention further discloses a control system, for controlling brightness of a light emitting diode (LED), comprising a single wire, a signal processing circuit comprising a single input terminal for receiving an input signal via the single wire, wherein the input signal comprises a plurality of pulse signals, a pulse width detection unit for generating a plurality of bits corresponding to the plurality of pulse signals according to a plurality of widths of the plurality of pulse signals and forming a source code, and a decoding unit for decoding the source code to generate a control code, a core circuit, for generating a control signal according to the control code, and a driving circuit for driving the LED and adjusting the brightness of the LED according to the control signal, wherein when a width of a first pulse signal of the plurality of pulse signals is smaller than a first duration, a first bit corresponding to the first pulse signal is a first bit value, and when a width of a second pulse signal of the plurality of pulse signals is greater than a second duration, a second bit corresponding to the second pulse signal is a second bit value.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram of a control system according to an embodiment of the present invention.

FIG. 2 illustrates a schematic diagram of a signal processing circuit according to an embodiment of the present invention.

FIG. 3 illustrates a schematic diagram of an input signal according to an embodiment of the present invention.

FIG. 4 illustrates a schematic diagram of a signal processing process according to an embodiment of the present invention.

FIG. 5 illustrates a relation diagram of a current of an LED corresponding to a control code according to an embodiment of the present invention.

### DETAILED DESCRIPTION

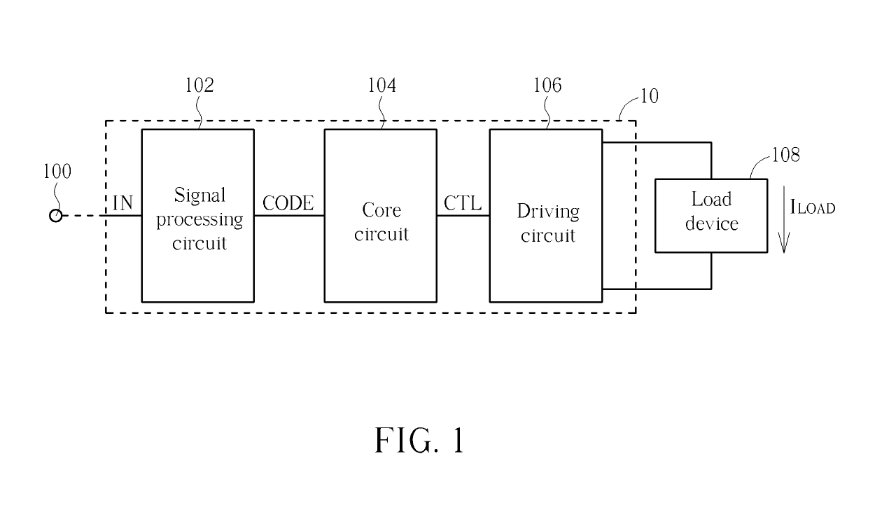

Please refer to FIG. 1, which illustrates a schematic diagram of a control system 10 according to an embodiment of the present invention. As shown in FIG. 1, the control system 10 is utilized for controlling a load device 108 and includes a signal processing circuit 102, a core circuit 104 and a driving circuit 106. The signal processing circuit 102 sequentially receives an external input signal IN and processes the input signal IN into a control code CODE. Noticeably, since the input signal IN is a single wire signal and is transmitted via a single pin 100, when the control system 10 is realized in an integrated circuit (IC), the single pin 100 is a package pin of the IC. The core circuit 104 is utilized for generating a control signal CTL according to the control code CODE to control the driving circuit 106. The core circuit 104 may be a central processor or a specially designed control circuit, and is not limited. The driving circuit 106 is utilized for driving the load device 108, and controlling a magnitude of a current I_{LOAD} flowing through the load device 108 according to the control signal CTL generated by the core circuit 104. For example, when the load device 108 is a light emitting diode (LED), the driving circuit 106 may be a constant-voltage driving circuit, a constant-current driving circuit, a pulse driving circuit or etc. for driving the LED to light and controlling the magnitude of the current flowing through the LED to achieve or approximate the design requirements, so as to make the current stable regardless of the influence of the supply voltage, the temperature, the forward bias voltage differences, or the other factors. In addition, the driving circuit 106 may also control the magnitude of the current flowing through the LED according to the control signal CTL to adjust the brightness of the LED.

In other words, the control system 10 utilizes the single pin 100 to receive the input signal IN, converts and decodes the input signal IN via the signal processing circuit 102, and controls the driving circuit 106 according to the control code CODE decoded by the signal processing circuit 102 to control the magnitude of the current I_{LOAD} flowing through the load device 108. Thereby, the control system 10 only utilizes the single pin to receive the external control signal and may decrease the pin number for saving the cost.

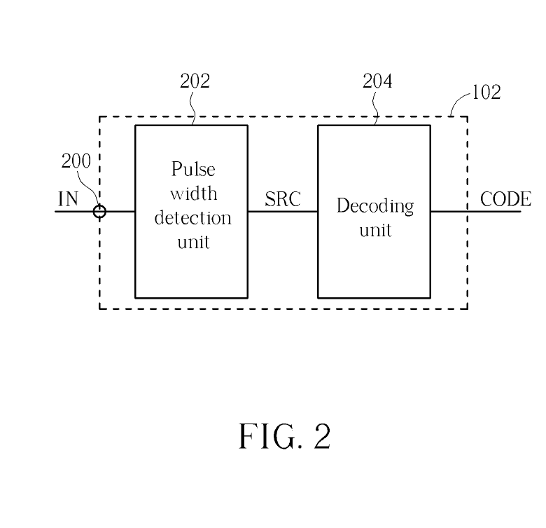

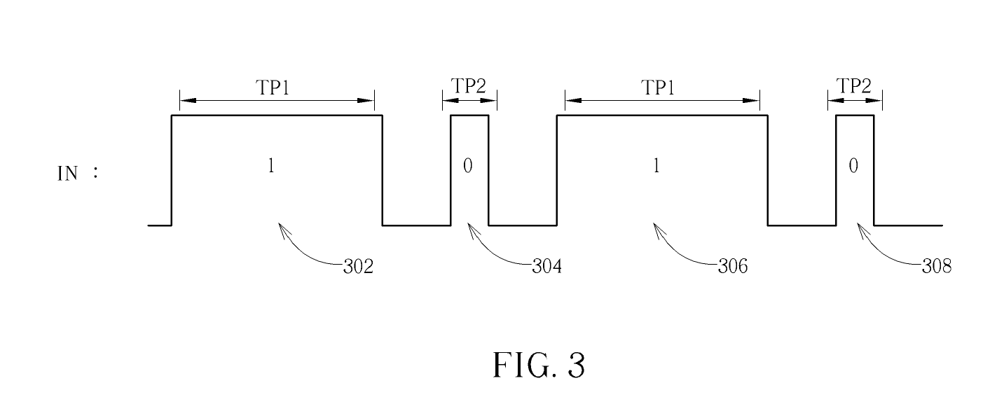

In detail, please refer to FIG. 2, which illustrates a schematic diagram of the signal processing circuit 102 according to an embodiment of the present invention. As shown in FIG. 2, the signal processing circuit 102 includes a single input terminal 200, a pulse width detection unit 202 and a decoding unit 204. In order to more clearly illustrate the operation of the signal processing circuit 102, please also refer to FIG. 3, which illustrates a schematic diagram of a example of the input signal IN in FIG. 2. As shown in FIG. 3, the input signal IN comprises pulse signals 302, 304, 306, 308, the widths of the pulse signals 302,306 are greater than a first duration TP1, and the widths of the pulse signals 304, 308 are smaller than a second duration TP2. The input signal IN is transmitted to the pulse width detection unit 202 via the single input terminal 200 with a single wire. The pulse width detection unit 202 sequentially detects the widths of the pulse signals 302, 304, 306, 308, generates the corresponding bit value as logical value 1 (marked in the pulse signals 302, 306 shown in FIG. 3) according to the widths of the pulse signals 302, 306 being greater than the first duration TP1, and generates the corresponding bit value as logical value 0 (marked in the pulse signals 304, 308 shown in FIG. 3) according to the widths of the pulse signals 304, 308 being smaller than the second duration TP2. Finally, the pulse width detection unit 202 collects the generated corresponding bits to form a source code SRC as 1010, and the obtained source code SRC is the code with control information, which is transferred from the external circuit to the control system 10. Then, the decoding unit 204 decodes the source code SRC to the control code CODE, which may be recognized by the core circuit 104, according to the design of the core circuit 104, so as to generate the control signal to control the driving circuit 106.

Thus, the external circuit may encode the control information, which is prepared to be transmitted, as a code, generate the corresponding pulse widths according to the bits of the code to be the input signal IN, and transmit the input signal IN to the control system 10. Thereby, the signal processing circuit 102 only utilizes the single wire to receive the input signal IN synchronously, converts the input signal IN according to the widths of the pulse signals to obtain the control information, and decodes to the control code CODE, so as to decrease the pin number of the control system 10.

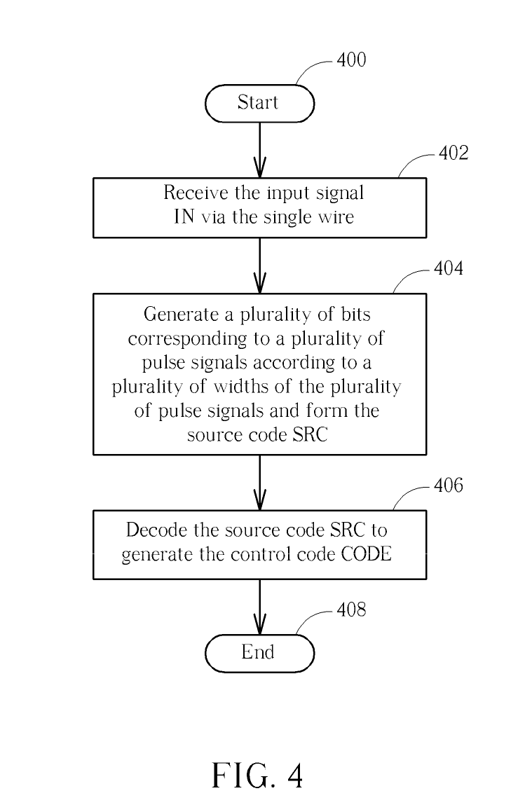

Operations of the signal processing unit 102 can be summarized in a signal processing process 40. As shown in FIG. 4, the signal processing process 40 includes the following steps:

Step 400: Start.

Step 402: Receive the input signal IN via the single wire.

Step 404: Generate a plurality of bits corresponding to a plurality of pulse signals according to a plurality of widths of the plurality of pulse signals and form the source code SRC.

Step 406: Decode the source code SRC to generate the control code CODE.

Step 408: End.

Detailed description of the signal processing process 40 can be referred from the foregoing description and is not further narrated herein for brevity.

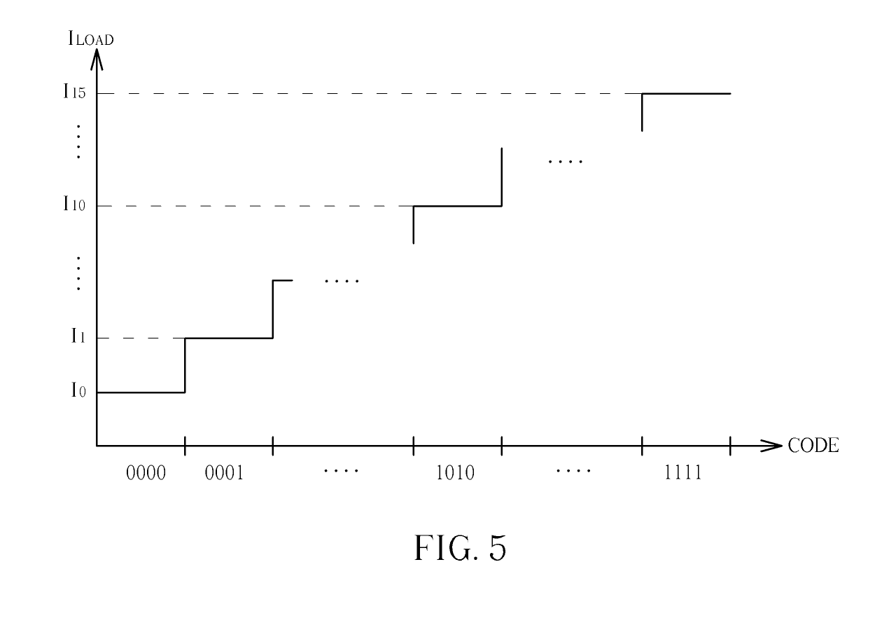

Furthermore, please refer to FIG. 5, which illustrates a relation diagram of the current I_{LOAD} of the load device 108 corresponding to the control code CODE according to an embodiment of the present invention. As shown in FIG. 5, by the operation of the core circuit 104 and the driving circuit 106, the control code CODE may be converted to control the magnitude of the current I_{LOAD} flowing through the load device 108, that is, when the control codes are 0000, 0001, . . . , 1010, . . . , 1111, the corresponding magnitude of the current I_{LOAD} are I0, I1, . . . , I10, . . . , I15. Thereby, when the load device 108 is the LED, the magnitude of the current I_{LOAD} may be controlled to adjust the brightness of the LED.

Note that, the above description is an embodiment of the present invention. Those skilled in the art can make modifications or alterations accordingly, and is not limited herein. For example, in FIGS. 2 and 3, the pulse width detection unit 202 generates the corresponding bit value as logical value 1 according to the widths of the pulse signals 302, 306 being greater than the first duration TP1, and generates the corresponding bit value as logical value 0 according to the widths of the pulse signals 304, 308 being smaller than the second duration TP2. However, in other embodiments, the pulse width detection unit 202 may also generate the corresponding bit value as logical value 0 according to the widths of the pulse signals 302, 306 being greater than the first duration TP1, and generate the corresponding bit value as logical value 1 according to the widths of the pulse signals 304, 308 being smaller than the second duration TP2.

Any uses for distinguishing the corresponding bit value according to the pulse signal width of the input signal IN are applied to the scope of the present invention, and are not limited herein. Furthermore, the first duration TP1 and the second duration TP2 are utilized for distinguishing the pulse signal width and also may be modified as the same duration accordingly. Thereby, the corresponding logic values, which may be 0 or 1, are obtained according to the same duration.

In addition, the length of the source code SRC maybe increased or decreased according to the actual requirement. The other pulse signal with the longer duration may also be utilized to represent the transmitted pulse signal of the input signal IN as a end pulse signal of the source code SRC, or a signal continued for a high potential or a signal continued for a low potential may also be utilized, and are not limited herein. The control code CODE can also be determined as the same with the source code SRC depending on the design of the core circuit, that is, the decoding unit 204 only simply duplicates the source code SRC to the control code CODE.

On the other hand, the control system 10 may utilize a storage circuit to store the generated control code CODE, and then the signal processing circuit 102 may receive the next control signal immediately. The core circuit 104 generates the control signal according to the stored control code CODE after the core circuit 104 performs a process, in order to increase the controlling reaction rate under the synchronous operation of the signal processing circuit 102 and the core circuit 104.

Furthermore, in addition to control the magnitude of the current of the load device 108, such as the LED, to adjust the brightness of the LED, the control system 10 may also control the voltage of the motor to adjust the speed of the motor in other application, control the voltage of the other high power lighting device to change the chromaticity of the lighting device, and may make modifications or alterations accordingly.

In summary, the conventional control system utilizes the multiple pins to receive the external control signals, such that the cost of the conventional control system is increased. In comparison, the present invention utilizes the single wire to receive the signals, and the pin number and cost of the control system may be decreased.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A signal processing method, for a single wire, comprising:
receiving an input signal via the single wire, wherein the input signal comprises a plurality of pulse signals;
generating a plurality of bits corresponding to the plurality of pulse signals according to a plurality of widths of the plurality of pulse signals and forming a source code; and
decoding the source code to generate a control code;
wherein when a width of a first pulse signal of the plurality of pulse signals is smaller than a first duration, a first bit corresponding to the first pulse signal is a first bit value, and when a width of a second pulse signal of the plurality of pulse signals is greater than a second duration, a second bit corresponding to the second pulse signal is a second bit value.

2. The signal processing method of claim 1, wherein the first bit value is logic value 1 and the second bit value is logic value 0.

3. The signal processing method of claim 1, wherein the first bit value is logic value 0 and the second bit value is logic value 1.

4. The signal processing method of claim 1, wherein the first duration is equal to the second duration.

5. The signal processing method of claim 1, wherein the source code is a binary code with variable length.

6. A signal processing circuit, for a single wire, comprising:
a single input terminal, for receiving an input signal via the single wire, wherein the input signal comprises a plurality of pulse signals;
a pulse width detection unit, for generating a plurality of bits corresponding to the plurality of pulse signals according to a plurality of widths of the plurality of pulse signals and forming a source code; and
a decoding unit, for decoding the source code to generate a control code;
wherein when a width of a first pulse signal of the plurality of pulse signals is smaller than a first duration, a first bit corresponding to the first pulse signal is a first bit value, and when a width of a second pulse signal of the plurality of pulse signals is greater than a second duration, a second bit corresponding to the second pulse signal is a second bit value.

7. The signal processing circuit of claim 6, wherein the first bit value is logic value 1 and the second bit value is logic value 0.

8. The signal processing circuit of claim 6, wherein the first bit value is logic value 0 and the second bit value is logic value 1.

9. The signal processing circuit of claim 6, wherein the first duration is equal to the second duration.

10. The signal processing circuit of claim 6, wherein the source code is a binary code with variable length.

11. A control system, for controlling brightness of a light emitting diode (LED), comprising:
a single wire;
a signal processing circuit, comprising:
a single input terminal, for receiving an input signal via a single wire, wherein the input signal comprises a plurality of pulse signals;
a pulse width detection unit, for generating a plurality of bits corresponding to the plurality of pulse signals according to a plurality of widths of the plurality of pulse signals and forming a source code; and
a decoding unit, for decoding the source code to generate a control code;
a core circuit, for generating a control signal according to the control code; and
a driving circuit, for driving the LED and adjusting the brightness of the LED according to the control signal;
wherein when a width of a first pulse signal of the plurality of pulse signals is smaller than a first duration, a first bit corresponding to the first pulse signal is a first bit value, and when a width of a second pulse signal of the plurality of pulse signals is greater than a second duration, a second bit corresponding to the second pulse signal is a second bit value.

12. The control system of claim 11, further comprising:
a storage circuit, for storing the control code;
wherein the core circuit generates the control signal according to the control code stored in the storage circuit.

13. The control system of claim 11, wherein the first bit value is logic value 1 and the second bit value is logic value 0.

14. The control system of claim 11, wherein the first bit value is logic value 0 and the second bit value is logic value 1.

15. The control system of claim 11, wherein the first duration is equal to the second duration.

16. The control system of claim 11, wherein the source code is a binary code with variable length.
